(19) United States
(12) Patent Application Publication
(10) Pub. No.: US 2019/0072831 A1
(43) Pub. Date: Mar. 7, 2019

(54) SUBSTRATE AND DISPLAY PANEL

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Xin GAI, Beijing (CN); Miao LIU, Beijing (CN); Xiuyun CHEN, Beijing (CN); Jieqiong WANG, Beijing (CN)

(21) Appl. No.: 15/743,032

(22) PCT Filed: Jul. 27, 2017
(86) PCT No.: PCT/CN2017/094680

§ 371 Date: Jan. 9, 2018

(30) Foreign Application Priority Data
Sep. 22, 2016 (CN) 201610842866.6

(51) Int. Cl. G02F 1/1362; G02F 1/1335; H01L 27/12

(52) U.S. Cl. CPC G02F 1/136286; G02F 1/133514; G02F 1/15; H01L 27/124; G02F 1/133512

(57) ABSTRACT

A substrate and a display panel are disclosed. The substrate is divided into a display area and a peripheral area surrounding the display area. A plurality of pixel units are provided in the display area. The substrate includes a plurality of selectively-light-transmissive units, and each of the plurality of pixel units is provided therein with a corresponding selectively-light-transmissive unit. Each of the plurality of selectively-light-transmissive units is in a light-transmissive state or a light non-transmissive state according to a received control signal.

### CROSS-REFERENCE TO RELATED APPLICATIONS

This is a National Phase Application filed under 35 U.S.C. 371 as a national stage of PCT/CN2017/094680, filed on Jul. 27, 2017, an application claiming the priority of Chinese Patent Application No. 201610842866.6, filed on Sep. 22, 2016, the contents of which are incorporated herein in their entirety by reference.

### TECHNICAL FIELD

The present disclosure relates to the field of display technology, and particularly relates to a substrate and a display panel including the substrate.

### BACKGROUND

When a liquid crystal display panel performs display, a gate driving circuit needs to be used to provide a scan signal to a gate line so as to charge a gate electrode of a thin film transistor. When a voltage at the gate electrode of the thin film transistor reaches a predetermined value, the thin film transistor is turned on, so that a liquid crystal capacitor formed between a pixel electrode and a common electrode can be charged, thereby controlling deflection of liquid crystal molecules. The higher the charging efficiency, the higher the response speed of deflection of liquid crystal molecules, and the high response speed is conducive to accurate display of an image.

How to improve the charging efficiency has become an urgent technical problem to be solved in the art.

### SUMMARY

According to an aspect of the present disclosure, there is provided a substrate, which is divided into a display area and a peripheral area surrounding the display area, and a plurality of pixel units are provided in the display area. The substrate includes a plurality of selectively-light-transmissive units, each of the plurality of pixel units is provided therein with a corresponding selectively-light-transmissive unit, and each of the plurality of selectively-light-transmissive units is in a light-transmissive state or a light non-transmissive state according to a received control signal.

According to an embodiment of the present disclosure, the plurality of selectively-light-transmissive units may be made of an electrochromic material.

According to an embodiment of the present disclosure, the substrate may further include a plurality of control electrodes, each of the plurality of control electrodes corresponds to one row of the plurality of selectively-light-transmissive units, and one row of the plurality of selectively-light-transmissive units is controlled by a corresponding control electrode.

According to an embodiment of the present disclosure, each of the plurality of control electrodes has one part in the display area and the other part in the peripheral area.

According to an embodiment of the present disclosure, the plurality of control electrodes may be made of a transparent electrode material.

According to an embodiment of the present disclosure, the substrate may further include a color filter layer and a black matrix.

According to another aspect of the present disclosure, there is provided a display panel including an array substrate and an opposite substrate. The opposite substrate is the substrate according to the present disclosure, the opposite substrate and the array substrate are provided opposite to each other, and positions of the plurality of selectively-light-transmissive units of the opposite substrate correspond to positions of thin film transistors of the array substrate.

According to an embodiment of the present disclosure, the positions of the plurality of selectively-light-transmissive units of the opposite substrate may correspond to positions of active layers of the thin film transistors of the array substrate.

According to an embodiment of the present disclosure, the display panel may further include a plurality of conductive elements between the opposite substrate and the array substrate, and each of the plurality of conductive elements is electrically connected to a gate electrode of a thin film transistor of the array substrate and a corresponding selectively-light-transmissive unit on the opposite substrate, respectively.

According to an embodiment of the present disclosure, the plurality of conductive elements may be disposed in the peripheral area of the opposite substrate and may be electrically connected to the gate electrodes of the thin film transistors of the array substrate through gate lines of the array substrate.

According to an embodiment of the present disclosure, the display panel may be a liquid crystal display panel.

According to the present disclosure, selectively-light-transmissive units are provided on a substrate, and when the substrate, serving as an opposite substrate, and an array substrate are assembled, positions of the selectively-light-transmissive units on the opposite substrate correspond to positons of thin film transistors on the array substrate. When the selectively-light-transmissive unit is in a light-transmissive state according to the received control signal, ambient light or backlight may pass through the selectively-light-transmissive unit to irradiate on the thin film transistor on the array substrate. When the thin film transistor is turned on, movement speeds of carriers are increased due to light irradiation, so that speed of charging a liquid crystal capacitor formed between a pixel electrode and a common electrode on the array substrate is increased. When the selectively-light-transmissive unit is in a light non-transmissive state according to the received control signal, light can be effectively blocked.

### BRIEF DESCRIPTION OF THE DRAWINGS

The accompanying drawings, which are used for providing a further understanding of the present disclosure and constitute a part of the specification, are used for explaining the present disclosure together with the following specific implementations, but are not intended to limit the present disclosure. In the drawings:

FIG. 1 is a schematic structural view of a substrate according to an embodiment of the present disclosure; and

FIG. 2 is a timing diagram for controlling the substrate shown in FIG. 1.

### DETAILED DESCRIPTION

Specific implementations of the present disclosure are described in detail below in conjunction with the accompanying drawings. It should be understood that, the specific implementations described herein are only used for describing and explaining the present disclosure, rather than limiting the present disclosure.

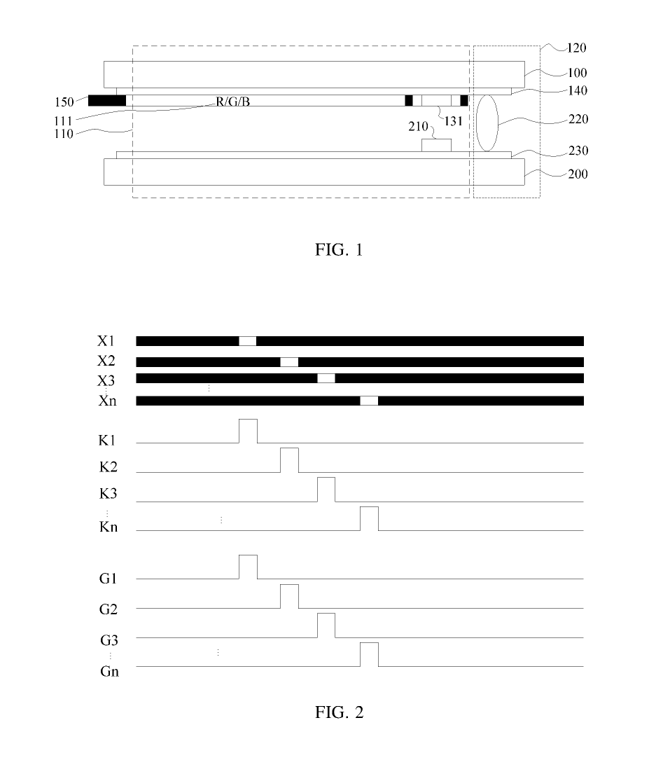

FIG. 1 is a schematic structural view of a substrate according to an embodiment of the present disclosure.

Referring to FIG. 1, a substrate 100 according to an embodiment of the present disclosure may be divided into a display area 110 and a peripheral area 120 surrounding the display area 110, and a plurality of pixel units 111 are provided in the display area 110. FIG. 1 shows a case where one pixel unit 111 includes three sub-pixel units R, G, and B, but the present disclosure is not limited thereto.

As shown in FIG. 1, the substrate 100 further includes a plurality of selectively-light-transmissive units 131, and each pixel unit 111 is provided therein with a corresponding selectively-light-transmissive unit 131. The selectively-light-transmissive unit 131 may be in either a light-transmissive state or a light non-transmissive state according to a received control signal.

When the substrate 100 that serves as an opposite substrate 100 and an array substrate 200 are assembled, positions of the selectively-light-transmissive units 131 on the opposite substrate 100 correspond to positions of thin film transistors 210 on the array substrate 200. In particular, the positions of the selectively-light-transmissive units 131 correspond to positions of active layers of the thin film transistors 210.

It should be noted that structure of the selectively-light-transmissive unit 131 is not particularly limited in the present disclosure, as long as the selectively-light-transmissive unit 131 can be in a light-transmissive state or a light non-transmissive state according to a received control signal. For example, the control signal may be a voltage signal, and when the control signal is at a high voltage level, the selectively-light-transmissive unit 131 is in a light-transmissive state, and when the control signal is at a low voltage level, the selectively-light-transmissive unit 131 is in a light non-transmissive state.

According to an embodiment of the present disclosure, the control signal for controlling the selectively-light-transmissive unit 131 may be a voltage signal from a gate line 230 of the array substrate 200. When the gate line 230 of the array substrate 200 is at a high voltage level, a thin film transistor 210 whose gate electrode is connected to the gate line 230 is turned on to charge a liquid crystal capacitor formed between a pixel electrode (not shown in the figures) and a common electrode (not shown in the figures) of the array substrate 200. In the meanwhile, the control signal at a high voltage level causes the selectively-light-transmissive unit 131 to be in a light-transmissive state, and ambient light or backlight can pass through the selectively-light-transmissive unit 131 to irradiate on the thin film transistor 210. In a case where the thin film transistor 210 is turned on, movement speeds of carriers in a conductive channel are increased due to light irradiation, and therefore, charging efficiency is improved, so that a voltage between the pixel electrode and the common electrode of the array substrate 200 reaches a desired grayscale voltage quickly. When the charging is completed, the gate line 230 of the array substrate 200 is at a low level, and the control signal at a low voltage level causes the selectively-light-transmissive unit 131 to be in a light non-transmissive state so as to block light effectively, and thus disordered arrangement of liquid crystal molecules between the array substrate 200 and the opposite substrate 100 caused by uncontrollable electric field at the thin film transistor 210 is avoided to avoid light leakage of a pixel.

According to an embodiment of the present disclosure, the selectively-light-transmissive unit 131 is made of an electrochromic material. In the present embodiment, the electrochromic material has a color that is changed reversibly and stably by applying a different voltage level so as to be in a light-transmissive state or a light non-transmissive state.

According to an embodiment of the present disclosure, the electrochromic material may be, for example, any one of vanadium pentoxide, vanadium dioxide, tungsten oxide, nickel oxide, and conductive polyethylene. However, the present disclosure is not limited thereto, and the electrochromic material may be other electrochromic material, as long as it can be in a light-transmissive state or a light non-transmissive state according to the received control signal.

It should be understood that the pixel units 111 of the substrate 100 are arranged in multiple rows and multiple columns, and accordingly, the selectively-light-transmissive units 131 corresponding to the pixel units are also arranged in multiple rows and multiple columns.

According to an embodiment of the present disclosure, as shown in FIG. 1, the substrate 100 may further include a plurality of control electrodes 140. Each of the plurality of control electrodes 140 corresponds to one row of selectively-light-transmissive units 131, and the selectively-light-transmissive units 131 in one row are controlled by the corresponding control electrode 140.

In a case where the gate line 230 of the array substrate 200 is at a high voltage level, the control electrode 140 can transmit the voltage signal having a high level to the corresponding selectively-light-transmissive unit 131, so that the selectively-light-transmissive unit 131 is in a light-transmissive state. According to an embodiment of the present disclosure, other control signal may be applied to the control electrode 140. For example, a control signal that is at a high voltage level or a low voltage level in synchronization with the gate line 230 of the array substrate 200 may be applied to the control electrode 140.

In the embodiment, each control electrode 140 corresponds to one row of selectively-light-transmissive units 131, and the selectively-light-transmissive units 131 in one row are controlled by the corresponding control electrode 140. Therefore, when the control signal applied to the control electrode 140 is at a high voltage level, all of the selectively-light-transmissive units 131 in one row are in a light-transmissive state at the same time, and when the control signal applied to the control electrode 140 is at a low voltage level, all of the selectively-light-transmissive units 131 in one row are in a light non-transmissive state at the same time. Therefore, when charging the liquid crystal capacitors formed between each row of pixel electrodes (i.e., the pixel electrodes connected to a single gate line 230) and the common electrode in the array substrate 200, the control electrode 140 corresponding to this row of pixel electrodes can simultaneously control all of the selectively-light-transmissive units 131 corresponding to this row to be in a light-transmissive state, thereby improving charging efficiency of charging the liquid crystal capacitors in each row.

As shown in FIG. 1, one part of the control electrode 140 is located in the display area 110, and the other part of the control electrode 140 is located in the peripheral area 120.

According to an embodiment of the present disclosure, the control electrode 140 may be made of a transparent electrode material. For example, the control electrode 140 may be made of indium tin oxide (ITO). However, the present disclosure is not limited thereto, and the control electrode 140 may be made of other transparent electrode material.

According to an embodiment of the present disclosure, as illustrated in FIG. 1, the substrate 100 may further include a color filter layer (not shown in the figures) and a black matrix 150. The color filter layer may include a plurality of color-resisting blocks, and each of the pixel units 111 may include a red color-resisting block R, a green color-resisting block G and a blue color-resisting block B. The black matrix 150 may surround each of the color resisting blocks to shield the data lines (not shown) and the gate lines 230 on the array substrate 200, so as to prevent backlight leakage. The black matrix 150 should be arranged at a position other than the position where the selectively-light-transmissive unit 131 is provided.

The substrate 100 according to the present disclosure may be applied to, for example, a liquid crystal display panel. As shown in FIG. 1, the display panel includes an array substrate 200 and an opposite substrate 100, which is the substrate according to the present disclosure. The opposite substrate 100 and the array substrate 200 are aligned and assembled, and the positions of the selectively-light-transmissive units 131 correspond to the positions of the thin film transistors 210 in the array substrate 200, respectively. More specifically, the positions of the selectively-light-transmissive units 131 correspond to the positions of the active layers of the thin film transistors 210, respectively.

In the display panel according to the present embodiment, the selectively-light-transmissive units 131 are provided at positions corresponding to the positions of the thin film transistors 210 (particularly, the positions of the active layers of the thin film transistors 210) of the array substrate 200. In a case where a control signal (e.g., a voltage signal from the gate line 230 of the array substrate 200) applied to the selectively-light-transmissive unit 131 is at a high voltage level, one row of thin film transistors 210 connected to the gate line 230 are turned on to start charging the liquid crystal capacitors formed between the pixel electrodes and the common electrode, and in the meanwhile, one row of selectively-light-transmissive units 131 corresponding to the row of thin film transistors 210 are in a light-transmissive state, so that ambient light or backlight can pass through the selectively-light-transmissive units 131 to irradiate on the thin film transistors 210, particularly, on the active layers of the thin film transistors 210, thereby increasing the charging efficiency. When the charging is completed, the gate line 230 is at a low voltage level, the row of thin film transistors 210 connected to the gate line 230 are turned off, and at the same time, the row of selectively-light-transmissive units 131 corresponding to the row of thin film transistors 210 are in a light non-transmissive state to effectively block light.

According to an embodiment of the present disclosure, the display panel may further include a plurality of conductive elements 220 provided between the opposite substrate 100 and the array substrate 200 to electrically connect the gate lines 230 on the array substrate 200 to the corresponding control electrodes 140 on the opposite substrate 100, respectively. In addition, the conductive element 220 may be provided in the peripheral area 120 to electrically connect a portion of the control electrode 140 located in the peripheral area 120 to the corresponding gate line 230 of the array substrate 200. According to the embodiment, the conductive elements 220 electrically connect the gate lines 230 on the array substrate 200 to the control electrodes 140 on the opposite substrate 100, so that voltage signals applied to the gate lines 230 of the array substrate 200 serve as control signals for controlling the selectively-light-transmissive units 131. When a gate drive circuit (not shown) supplies a voltage signal at a high voltage level, charging of the liquid crystal capacitors formed between the pixel electrodes and the common electrode starts. At this point, the control electrode 140 supplies a control signal at a high voltage level to the selectively-light-transmissive units 131 to control the selectively-light-transmissive units 131 to be in a light-transmissive state, and thus, ambient light or backlight irradiates on the thin film transistors 210 after passing through the selectively-light-transmissive units 131. Consequently, movement speeds of carriers in conductive channels of the thin film transistors 210 are increased, thereby improving the charging efficiency. In addition, the conductive elements 220 in the peripheral area 120 will not affect the display effect of the display panel.

The conductive element 220 may include a conductive metal ball. According to an embodiment of the present disclosure, the conductive metal ball may be formed by electroplating a metal having good electrical conductivity on an outer surface of a spherical elastic polymer material, so as to have a certain degree of elasticity. However, the present disclosure is not limited thereto, and the conductive element 220 may have other structure.

FIG. 2 is a timing diagram for controlling the substrate shown in FIG. 1.

Referring to FIG. 1 and FIG. 2, X1 to Xn show changes in state of each row of selectively-light-transmissive units 131 according to control signals, K1 to Kn are control signals (voltage signals) respectively received by the control electrodes 140, G1 to Gn are voltage signals respectively applied to the gate lines 230, and ‘n’ is the number of rows of pixel units. When the gate line 230 in a first row receives a voltage signal at a high voltage level, the control electrode 140 in the first row corresponding to the gate line 230 in the first row receives a voltage signal at a high voltage level, so that the control electrode 140 in the first row controls the selectively-light-transmissive units 131 in the first row to be in a light-transmissive state. When the gate line 230 in the first row receives a voltage signal at a low voltage level, the control electrode 140 in the first row corresponding to the gate line 230 in the first row also receives a voltage signal at a low voltage level synchronously, so that the control electrode 140 in the first row controls the selectively-light-transmissive units 131 in the first row to be in a light non-transmissive state. The foregoing operation process of the first row also applies to each of the remaining rows, and thus is not repeated herein.

Although the case where a voltage signal applied to the gate line 230 serves as a control signal for controlling the selectively-light-transmissive unit 131 is described, the present disclosure is not limited thereto. For example, a control signal that is at a high voltage level or a low voltage level in synchronization with a voltage signal applied to the gate line 230 may be applied to the selectively-light-transmissive unit 131.

The display panel according to the present disclosure is described by taking a liquid crystal display panel as an example, but the present disclosure is not limited thereto. The substrate according to the present disclosure may also be applied to a display panel such as an OLED display panel.

It could be understood that the above embodiments are merely exemplary embodiments adopted for describing the principle of the present disclosure, but the present disclosure is not limited thereto. Various variations and improvements may be made by those of ordinary skill in the art without departing from the spirit and essence of the present disclosure, and these variations and improvements shall also be regarded as falling into the protection scope of the present disclosure.

1. A substrate, divided into a display area and a peripheral area surrounding the display area, a plurality of pixel units being provided in the display area, the substrate comprising:
a plurality of selectively-light-transmissive units, wherein each of the plurality of pixel units is provided therein with a corresponding selectively-light-transmissive unit, and each of the plurality of selectively-light-transmissive units is in a light-transmissive state or a light non-transmissive state according to a received control signal.

2. The substrate of claim 1, wherein the plurality of selectively-light-transmissive units are made of an electrochromic material.

3. The substrate of claim 1, further comprising a plurality of control electrodes, wherein each of the plurality of control electrodes corresponds to one row of the plurality of selectively-light-transmissive units, and one row of the plurality of selectively-light-transmissive units is controlled by a corresponding control electrode.

4. The substrate of claim 3, wherein each of the plurality of control electrodes has one part in the display area and the other part in the peripheral area.

5. The substrate of claim 4, wherein the plurality of control electrodes are made of a transparent electrode material.

6. The substrate of claim 1, further comprising a color filter layer and a black matrix.

7. A display panel comprising an array substrate and an opposite substrate, wherein the opposite substrate is divided into a display area and a peripheral area surrounding the display area, a plurality of pixel units being provided in the display area, the opposite substrate comprises:
a plurality of selectively-light-transmissive units, wherein each of the plurality of pixel units is provided therein with a corresponding selectively-light-transmissive unit, and each of the plurality of selectively-light-transmissive units is in a light-transmissive state or a light non-transmissive state according to a received control signal,
the opposite substrate and the array substrate are provided opposite to each other, and positions of the plurality of selectively-light-transmissive units of the opposite substrate correspond to positions of thin film transistors of the array substrate, respectively.

8. The display panel of claim 7, wherein the positions of the plurality of selectively-light-transmissive units of the opposite substrate correspond to positions of active layers of the thin film transistors of the array substrate, respectively.

9. The display panel of claim 7, further comprising a plurality of conductive elements between the opposite substrate and the array substrate, wherein each of the plurality of conductive elements is electrically connected to a gate electrode of a thin film transistor of the array substrate and a corresponding selectively-light-transmissive unit on the opposite substrate, respectively.

10. The display panel of claim 9, wherein the plurality of conductive elements are disposed in the peripheral area of the opposite substrate and electrically connected to the gate electrodes of the thin film transistors of the array substrate through gate lines of the array substrate.

11. The display panel claim 7, wherein the display panel is a liquid crystal display panel.

12. The display panel of claim 7, wherein the plurality of selectively-light-transmissive units are made of an electrochromic material.

13. The display panel of claim 7, wherein the opposite substrate further comprises a plurality of control electrodes, wherein each of the plurality of control electrodes corresponds to one row of the plurality of selectively-light-transmissive units, and one row of the plurality of selectively-light-transmissive units is controlled by a corresponding control electrode.

14. The display panel of claim 13, wherein each of the plurality of control electrodes has one part in the display area and the other part in the peripheral area.

15. The display panel of claim 14, wherein the plurality of control electrodes are made of a transparent electrode material.

16. The display panel of claim 7, wherein the opposite substrate further comprises a color filter layer and a black matrix.
